(19) United States
(12) Patent Application Publication
(10) Pub. No.: US 2021/0341231 A1
(43) Pub. Date: Nov. 4, 2021

(54) FLOW DISTRIBUTOR FOR COOLING AN ELECTRICAL COMPONENT, A SEMICONDUCTOR MODULE COMPRISING SUCH A FLOW DISTRIBUTOR, AND METHOD OF MANUFACTURING THE SAME

(71) Applicant: DANFOSS SILICON POWER GMBH, Flensburg (DE)

(72) Inventor: Georg Wecker, Nordborg (DK)

(21) Appl. No.: 17/285,019

(22) PCT Filed: Sep. 17, 2019
(86) PCT No.: PCT/EP2019/074892

§ 371 Date: Apr. 13, 2021

(30) Foreign Application Priority Data
Oct. 15, 2018 (DE) 10 2018 217 652.3

(51) Int. Cl. F28F 9/22; H01L 23/46; B33Y 80/00

(52) U.S. Cl. CPC F28F 9/22; B33Y 80/00; H01L 23/46

(57) ABSTRACT

A flow distributor (1) is provided for distributing a heat transporting fluid flow (2) of an electrical component across a surface to be cooled and/or heated by the fluid. The distributor includes at least one flow channel configured to direct the fluid flow across the surface, the flow channels being delimited on either side by walls (4) so as to form a path (6) for the fluid flow (2) within the flow channels (3), and comprising wall sections (5) extending into the at least one flow channel (3); and at least one of the wall sections (5) includes at least one bypass passage (7) to connect two adjacent spaces (8) separated by the wall section (5) where the at least one bypass passage (7) extends from one side of the wall section to the other one with an inclined orientation (10) so as to create a short circuit flow (9) for apart of the fluid flow (2). Furthermore, a method of manufacturing such a flow distributor is provided, having an insert with the wall structure of the inventive flow distributor which is manufactured by injection molding or by 3D-printing.

### CROSS REFERENCE TO RELATED APPLICATIONS

This application is a National Stage application of International Patent Application No. PCT/EP2019/074892, filed on Sep. 17, 2019, which claims priority to German Application No. 102018217652.3 filed on Oct. 15, 2018, each of which is hereby incorporated by reference in its entirety.

### TECHNICAL FIELD

The invention concerns a flow distributor for distributing a heat transporting fluid flow of an electrical component, a semiconductor module comprising such a flow distributor, and a method of manufacturing such a flow distributor.

### BACKGROUND

Flow distributors for distributing a heat transporting fluid flow within an electrical component, in particular within a semiconductor module having such a flow distributor, for example for heating and/or cooling such an electrical component are known. Methods of manufacturing such a flow distributor are also known in the prior art.

Electrical components in general and semiconductor devices in particular generate heat during their operation. As far as a reliable operation of the semiconductor devices is concerned, the heat generated by themselves is disadvantageous. The heat generated by the electrical or electronic components usually acts to deteriorate the operation of the semiconductor device. Therefore, for high power semiconductor devices, it is necessary to cool the device during operation to maintain acceptable device performance. Techniques for removing heat from a semiconductor device typically includes convection and/or conduction. It is for that reason why convection fans are quite often attached to a semiconductor package housing. Furthermore, it has been known to integrate a heat-sink into a semiconductor package. This heat-sink draws heat away from the semiconductor device, which can be air-cooled or liquid-cooled, depending on the particular application.

### SUMMARY

Therefore, it is the object of the present invention to create a cooling system, in particular for electronic components, in particular for semiconductor modules, having a flow distributor that enables a flow distribution that forms the basis for an increased heat transfer rate to increase the efficiency of cooling and/or heating such electronic devices without a loss in compactness of the component and without a considerable increase in manufacturing effort and costs.

This object is solved for a flow distributor with the features according to claim 1 or 6, for a semiconductor module with the features according to claim 13, for an insert with a wall structure of a flow distributor according to claim 14, and for methods of manufacturing a flow distributor with the features according to claim 16 or 17, respectively. Further embodiments for the flow distributor and for the method of manufacturing are defined in the dependent claims.

According to the inventions, a flow distributor distributes a heat transporting fluid flow of an electrical component from an inlet manifold to an outlet manifold across a surface cooled and/or heated by the fluid. According to the invention, the distributor comprises at least one flow channel which is configured to direct the fluid flow from the inlet manifold to the outlet manifold across the surface to take up heat energy and to transport it away from the place it is generated or to a place where heating is needed. The inventive flow channel is separated from other flow channels and is delimited on either side by walls so as to form a path for the fluid flow within the flow channel, and comprising wall sections extending into the flow channels. By directing the fluid flow around these wall sections the fluid flow increases its degree of turbulence to increase heat transfer efficiency rate. According to the invention at least one wall section comprises at least one bypass passage to connect two adjacent spaces which are separated by the wall sections directly through the wall section with an inclined orientation so that the bypass creates additionally a short circuit fluid flow for a part of the fluid flow and increases the swirl within the flow channel so that the degree of turbulence and hence the heat transfer rate is increased without increasing the velocity of the fluid flow through the channels. Otherwise this would mean that more power will be required for pumping the fluid flow through the device which in turn increases the costs of operation of for example semiconductor modules having such a flow distributor.

By the term “inclined orientation” it is to be understood within the frame work of this invention a direction of the bypass opening or hole, respectively in the wall section that facilitates the separation of a part of the fluid flow from one space to a neighboring space. This means, that inclined orientation could be, with regard to the general main direction of the fluid flow through the fluid channel, between −45° and +45°, which according to a main embodiment is arranged in a horizontal angle α whilst it could also be a vertical angle β as well as an arrangement in an oblique way so that the inclined orientation of the bypass in the wall section can also be horizontally and vertically arranged, that means arranged in an oblique way, defining an angle α of inclination with regard to the longitudinal direction of the fluid flow and/or an angle β of inclination with regard to a horizontal plane through the wall sections extending into the flow channel, preferably perpendicular to the horizontal plane. Such an inclined orientation would mean that a separation of a part of the fluid flow from the main flow alongside the wall section can easily pass through this bypass without an otherwise considerable obstacle for the fluid flow reducing the amount of fluid flow passing through a bypass which is not oriented in any inclined way.

According to a further embodiment, the wall section comprises at least one bypass passage, the inclined orientation of which has an angle of orientation with regard to the longitudinal direction of the walls. This means that the inclination facing towards the flow direction of the fluid flow alongside the wall section facilitates a part of the fluid flow to bypass through the wall section and to increase turbulence in general and the swirl of fluid flow in the neighboring space in particular so that the heat transporting fluid flow increases its capacity to take up more heat or to direct more heat to a place which for example is to be heated instead of being cooled. It is understood that swirl in its meaning within this application describes a rotating component of the velocity of a moving fluid normal to the general forward velocity of the fluid. According to the invention, the inventive flow distributor can be used both for cooling and heating. Cooling might be the major kind of application of this inventive device, though it could also be used for heating purposes when required.

According to a further embodiment, it is preferred that there is a plurality of wall sections within a flow channel and each of the wall sections comprise a plurality of bypass passages, which could mean that in particular the wall sections could also be perforated with the perforation holes being in an inclined orientation in the respective wall section.

Preferably, according to the further embodiment, the dimension of the bypass channels are adapted to the amount of fluid flow that should be separated from the main flow through the bypass channel from one space to the neighboring one. The dimensions of the bypass channels are such that preferably up to 40%, in particular up to 30%, more particular up to 15 to 20% and even more particular up to 10 to 15% of the fluid flow being conducted through the bypass channels to the respective space within the respective flow channel.

According to another embodiment, a flow distributor distributes a heat transporting fluid flow of an electrical component from an inlet manifold to an outlet manifold across a surface cooled and/or heated by the fluid. According to the invention, the distributor comprises at least one flow channel which is configured to direct the fluid flow from the inlet manifold to the outlet manifold across the surface to take up heat energy and to transport it away from the place it is generated or to a place where heating is needed. The inventive flow channel is separated from other flow channels and is delimited on either side by baffle walls which extend in longitudinal direction of the flow channel and comprises guide wall sections, which extend substantially perpendicular to the longitudinal direction of the flow channel so as to form a meandering path for the fluid flow within the flow channel. By directing the fluid flow around these baffle walls within the flow channel, the fluid flow increases its degree of turbulence to increase heat transfer efficiency rate. According to the invention at least one guide wall section comprises at least one bypass passage to connect two adjacent meandering spaces which are separated by the guide wall sections directly through the guide wall section with an inclined orientation so that the bypass creates additionally a short circuit fluid flow for a part of the fluid flow and increases the swirl within the flow channel so that the degree of turbulence and hence the heat transfer rate is increased without increasing the velocity of the fluid flow through the channels. Otherwise this would mean that more power will be required for pumping the fluid flow through the device which in turn increases the costs of operation of for example semiconductor modules having such a flow distributor.

By the term “inclined orientation” it is to be understood within the frame work of this invention a direction of the bypass opening or hole, respectively in the guide wall section that facilitates the separation of a part of the fluid flow from one meandering space to a neighboring meandering space. This means, that inclined orientation could be, with regard to the general main direction of the fluid flow through the fluid channel, between −45° and +45°, which according to a main embodiment is arranged in a horizontal angle α whilst it could also be a vertical angle β as well as an arrangement in an oblique way so that the inclined orientation of the bypass in the guide wall section can also be horizontally and vertically arranged, that means arranged in an oblique way, defining an angle α of inclination with regard to the longitudinal direction of the fluid flow and/or an angle β of inclination with regard to a horizontal plane through the guide wall sections extending perpendicular to the horizontal plane. Such an inclined orientation would mean that a separation of a part of the fluid flow from the main flow alongside the guide wall section can easily pass through this bypass without an otherwise considera- ble obstacle for the fluid flow reducing the amount of fluid flow passing through a bypass which is not oriented in any inclined way.

According to a further embodiment, the guide wall section comprises at least one bypass passage, the inclined orientation of which has an angle of orientation with regard to the longitudinal direction of the baffle walls. This means that the inclination facing towards the flow direction of the fluid flow alongside the guide wall section facilitates a part of the fluid flow to bypass through the guide wall section and to increase turbulence in general and the swirl of fluid flow in the neighboring meandering space in particular so that the heat transporting fluid flow increases its capacity to take up more heat or to direct more heat to a place which for example is to be heated instead of being cooled. It is understood that swirl in its meaning within this application describes a rotating component of the velocity of a moving fluid normal to the general forward velocity of the fluid. According to the invention, the inventive flow distributor can be used both for cooling and heating. Cooling might be the major kind of application of this inventive device, though it could also be used for heating purposes when required.

According to a further embodiment, it is preferred that there is a plurality of guide wall sections within a flow channel and each of the guide wall sections comprise a plurality of bypass passage, which could mean that in particular the guide wall sections could also be perforated with the perforation holes being in an inclined orientation in the respective guide wall section. The inclined orientation of the perforation holes is such that the fluid flow can be separated from one meandering space to the neighboring meandering space without any considerable increase in flow resistance, rather, the inclined orientation of the bypass holes in the guide wall sections makes it easier for the flow to use the bypass holes instead of flowing around the complete guide wall section.

Preferably, according to the further embodiment, the dimension of the bypass channels are adapted to the amount of fluid flow that should be separated from the main flow through the bypass channel from one meandering space to the neighboring one. The dimensions of the bypass channels are such that preferably up to 40%, in particular up to 30%, more particular up to 15 to 20% and even more particular up to 10 to 15% of the fluid flow being conducted through the bypass channels to the respective meandering space within the respective flow channel.

Preferably, according to one further embodiment, the flow distributor comprises a housing having the inlet manifold and the outlet manifold for the fluid flow and comprising a bathtub for receiving an insert having incorporated the wall structure of the fluid distributor, wherein the insert is covered by a closing plate to seal the bathtub towards its upper side. This means that the flow distributor consists of a separate component that can be placed at the cooling or heating space of an electrical component so as to implement the new inventive kind of cooling and/or heating flow for the electric component without amending the channel concept of the design of the entire module component.

Preferably, this insert comprises a two-part design comprising a lower structure and an upper counter structure each having a wall structure to fit to each other when assembled and its closing plate being integrally formed with the upper counter structure. This so-called double part structure would form the basis for a decreased amount of manufacturing steps because the bypass channels can be arranged at one side of the two-part form, that means either in the lower part or in the upper part or could also be arranged both within the upper and the lower part so that when the upper and the lower part are being assembled, the correct dimension and the correct size of the bypass channel will be provided.

According to a further embodiment, a semiconductor module is provided which makes use of a flow distributor according to claim 1 and the respective dependent claims. Such a semiconductor module with the inventive flow distributor could be used for the respective purposes of application for a high compact design with a higher degree of cooling and/or heating so that the general operation efficiency and operation reliability are achieved.

According to one further aspect of the invention, a method of manufacturing a flow distributor is provided, which comprises an insert with a wall structure of the flow distributor according to anyone of the claims 1 with the dependent claims directed to the flow distributor, wherein the flow distributor is manufactured by 3D-printing or by injection molding. The use of 3D-printing is particularly advantageous with regard to more or less complicated and optimized bypass channels within the wall structure of the guide wall sections.

According yet another aspect of the invention, an insert is provided which comprises a wall structure of a flow distributor according to anyone of claims 1 to 6, the insert being manufactured by 3D-printing or injection molding. 3D-printing for an insert with such an inventive wall structure is particularly advantageous because any angle of inclination and any angle of inclination of the bypass holes within the bypass channels as well as a varying number of such holes in the bypass channels can be manufactured with a manufacturing amount being relatively low.

And yet another aspect of the present invention is directed to a method of manufacturing a flow distributor wherein an insert having the wall structure of the flow distributor according to anyone of claims 1 to 6 is manufactured by 3D-printing. This inventive method comprises the following steps:
a) providing a computer-readable medium having computer-executable instructions which are adapted to cause a 3D-printer to print the flow distributor; and
b) forming the flow distributor using a 3D-printing or additive manufacturing apparatus.

According to a further aspect of the invention, a computer-readable me- dium with computer-executable instructions adapted to cause a 3D-printer to print a flow distributor according to anyone of claims 1 to 6 is provided. The computer-readable medium including the computer-executable instructions form the basis for controlling a 3D-printing or additive manufacturing apparatus, respectively. By means of this, a flow distributor comprising an insert with a corresponding wall structure according to the invention can be manufactured.

### BRIEF DESCRIPTION OF THE DRAWINGS

Further specific features, details, and applications will be described by referring to the attached drawings. In the drawings:

FIG. 1 shows a three-dimensional view of a flow channel structure according to the invention;

FIG. 2 shows the structure according to FIG. 1 at a different view angle also in three-dimensional representation;

FIG. 3 shows a plan view onto the flow channel structure according to the invention;

FIG. 4 shows the fluid flow through the flow channel according to the prior art, that means without bypass passages in the guide wall sections;

FIG. 5 shows the basic structure of the flow channel according to FIG. 4, however with inventive bypass passages in the guide wall sections to increase swirl in the flow passage;

FIG. 6 shows a separate insert having bypass passages within the guide wall sections, the meandering flow channel comprising rounded corners;

FIG. 7 an insert according to FIG. 6 with the meandering flow channel comprising corner edges;

FIG. 8a a sectional view of a bypass passage having an angle β with regard to a horizontal plane;

FIG. 8b a sectional plan view of a bypass passage comprising an angle α with regard to the longitudinal direction of the fluid flow within the flow channel;

FIGS. 9a, b, c cross-sectional plan views of bypass passages of different shape and direction of a certain meandering chamber; and

FIGS. 10a, b, c a representation of the angle of inclination of the bypass passage at a cross-sectional plan view, the angle of inclination defined with regard to the direction of fluid flow for meandering spaces arranged adjacent to each other.

### DETAILED DESCRIPTION

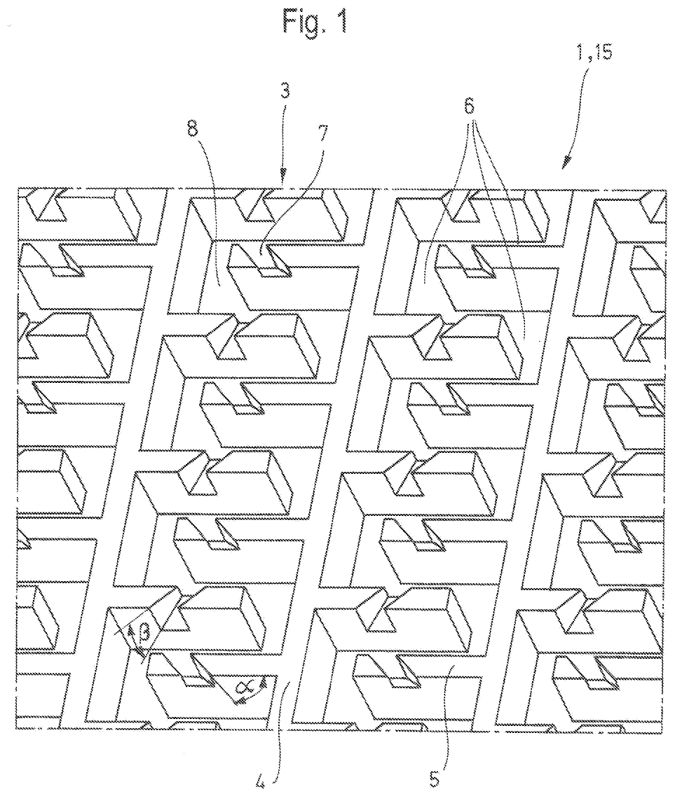

FIG. 1 shows a flow distributor 1 in a three-dimensional view as a partial view of an insert. There are four flow channels 3 extending from bottom to top and being delimited by baffle walls 4 separating the various flow channels 3 from each other. Guide wall sections 5 extend into the flow channels from either sides of the baffle walls so as to define a meandering path 6 within the respective flow channel 3. The guide wall sections 5 comprise bypass passages 7 that are oriented in an inclined way towards the direction of flow of the fluid flow 2 when flowing through the flow channel 3 on its meandering path 6. The bypass passages 7 are both inclined in the main direction of flow of the fluid flow 2 and form openings of the flow channel 3 towards its top which are covered by a closing plate to form closed bypass passages and closed flow channels 3 at their top regions, the closing plate not being represented in FIG. 1.

The bypass passages 7 are arranged such in their inclined orientation 10 that a part of the fluid flow 2 separates from the main flow to the bypass passages 7 so as to create an additional swirl within the meandering spaces 8 to increase the heat transfer rate from the wall structure of the insert 15 to the fluid flow 2 and vice versa.

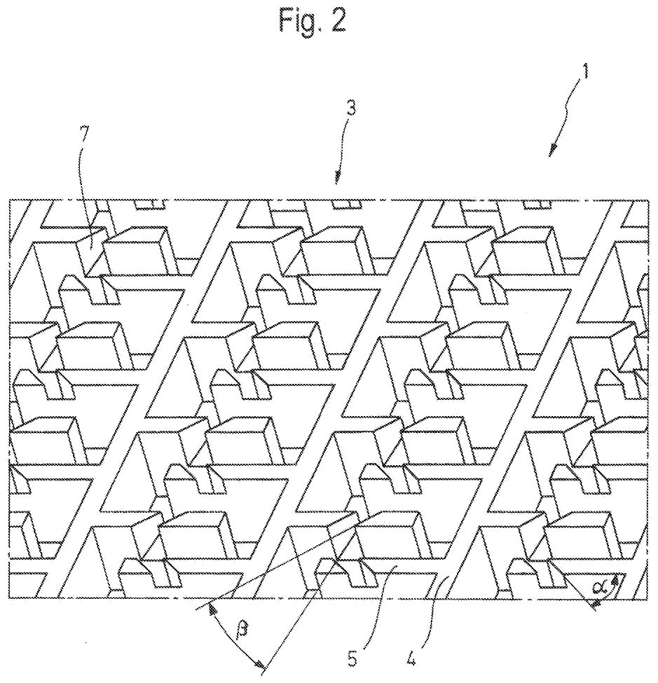

FIG. 2 depicts a three-dimensional view according to FIG. 1 with a different view angle, though with an identical wall structure. In FIG. 2, it can also clearly be seen that the bypass passages 7 are inclined in two directions, one direction forming an acute angle α with regard to the flow direction of the fluid flow 2 and additionally thereto an inclination forming an acute angle β with regard to the height of the guide wall sections from bottom to top of the flow channel 3. Such a bidirectional orientation of the bypass passage 7 with its oblique arrangement ensures additional swirl in the meandering space so that there is much less laminar flow in the meandering spaces when the fluid flow 2 passes through the flow channel on its meandering path 6.

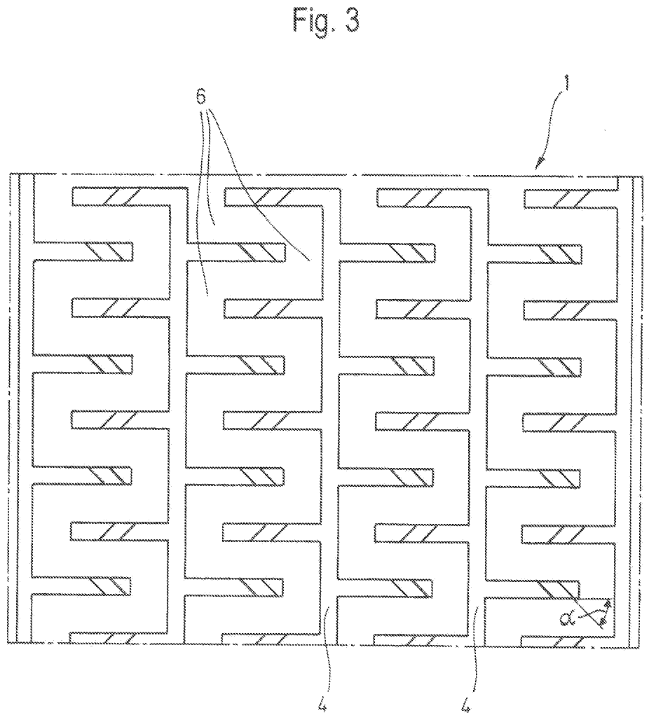

FIG. 3 shows a plan view onto the wall structure according to FIGS. 1 and 2 including the meandering path 6 for the fluid flow 2. The bypass passages 7 are arranged in an inclined way as described with regard to FIGS. 1 and 2, at the angle α with regard to the longitudinal direction of fluid flow.

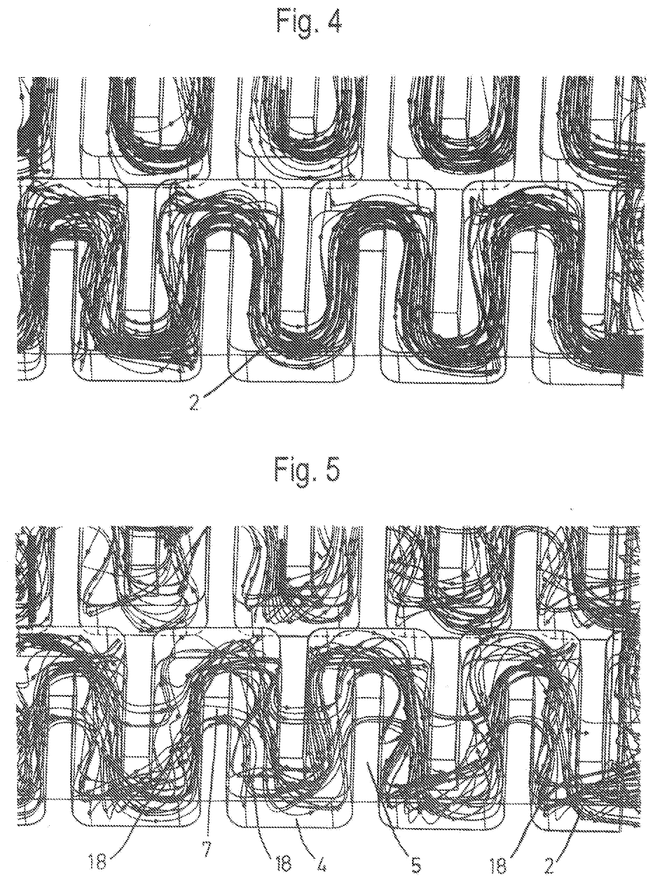

FIGS. 4 and 5 represent a comparison of the fluid flow 2 on its meandering paths 6 through the meandering spaces 8. FIG. 4 shows a representation without the inventive bypass passages. FIG. 5 shows a representation with the inventive bypass passages 7. Whilst in FIG. 4 the fluid flow 2 is more or less a laminar one despite of the meandering path 6 the fluid flow 2 takes through the flow channel 3, FIG. 5 represents that there is much more swirl and much less laminar flow within the flow channel 3 of the fluid flow 2 on its meandering paths through the insert. The swirl can be seen as an example at the locations being referred to by reference numeral 18. This additional bypass passage 7 increases the heat transfer efficiency within the flow channel considerably.

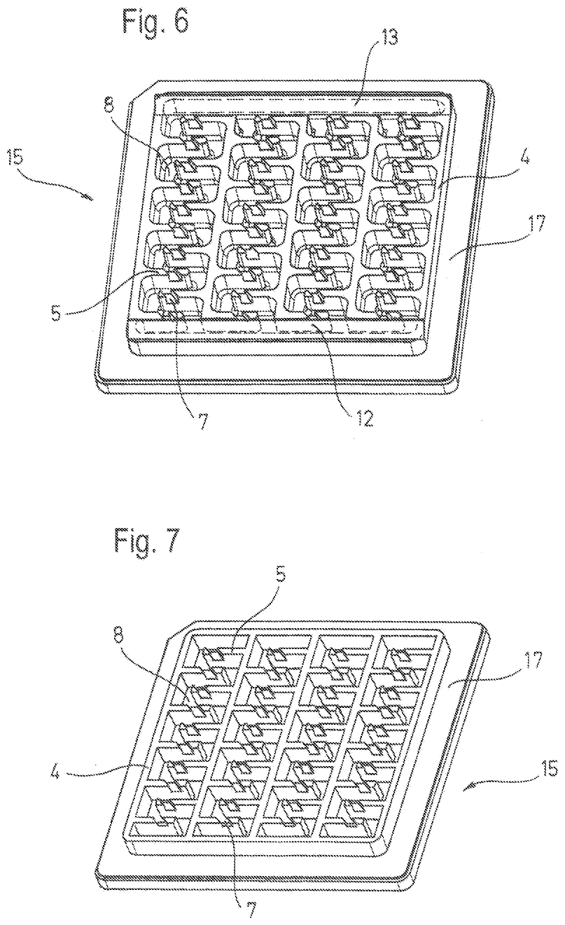

FIG. 6 shows a separate insert 15 as a lower structure 17 having bypass passages 7 within the guide wall sections 5, the meandering flow channel comprising rounded corners. The flow channel comprises meandering spaces 8 through which the fluid flow is flowing both around the guide wall sections and through the bypass passages 7. Once the insert 15 has been placed into a recess in a casing a lid closes up the insert and rests upon the upper surface of the flow channel structure so as to form closed flow channels 3 with bypass passages 7 in the guide wall sections 5 forming a meandering path for the fluid flow through the flow channel. The lid closing up the insert on its top can also be formed with a counter structure being form-congruent to the structure formed at the insert so that once the lid with the counter structure closes the recess with the insert therein a complete flow channel is formed. The advantage of subdividing the insert so to say into two parts of the structure is that the holes for the bypass passages need not be manufactured into the guide wall sections 5, it is easier with regard to manufacturing to cut out portions of the two respective counter structures from the respective top sides of the guide wall sections 5. The fluid flow flows from inlet manifold 12 to outlet manifold 13 through the meandering flow path.

FIG. 7 represents a similar embodiment as in FIG. 6 except for the fact that the rounded corners of the meandering path is replaced by corner edges. Otherwise all the elements are similar to what has been described with regard to FIG. 6 embodiment. For sake of simplicity the inlet manifold 12 and the outlet manifold 13 are not shown.

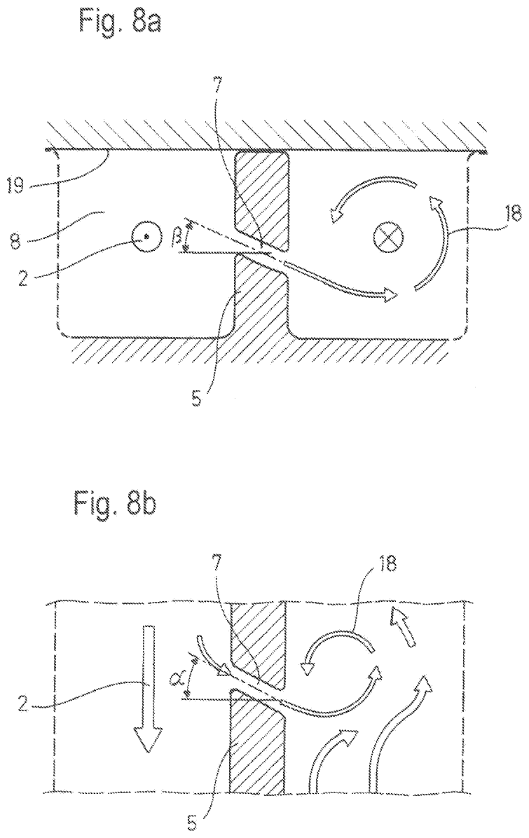

In FIG. 8a a sectional view with the bypass passages is represented from which it can be seen, that the bypass passage 7 is arranged at an angle β with regard to a horizontal plane, the horizontal plane being directed such that it extends in the direction of flow of the fluid flow through the flow channel. The sectional view represents that the fluid flow in the left meandering chamber is directed from the drawing plane upwards whilst the fluid flow in the neighboring meandering chamber is from the drawing plane downwards. It can be seen from FIG. 8a that by bypassing a part of the fluid flow 2 from the left meandering chamber through the bypass passage 7 to the neighboring bypass chamber an additional swirl 18 is induced that causes an increase of turbulence and hence an improved heat transfer rate for transporting away energy for an element to be cooled or for introducing energy to an element to be heated. Each meandering space 8 is arranged adjacent to a surface 19 to be cooled or heated, respectively.

FIG. 8b shows a sectional plan view with a bypass passage comprising an angle α with regard to the direction of fluid flow. Again the same principle is represented, namely that a part of the fluid flow 2 is separated and fed through the bypass passage 7 from the meandering chamber on the left side to the neighboring meandering chamber on the right side creating an additional swirl 18 in the neighboring meandering chamber so as to increase turbulence of the fluid flow 2 in the neighboring chamber.

From FIGS. 8a and 8b it can be seen, that the bypass passage 7 has an oblique arrangement comprising an angle β with regard to a horizontal plane and an angle α with regard to the longitudinal direction of the fluid flow as well as to the longitudinal direction of the guide wall section 5.

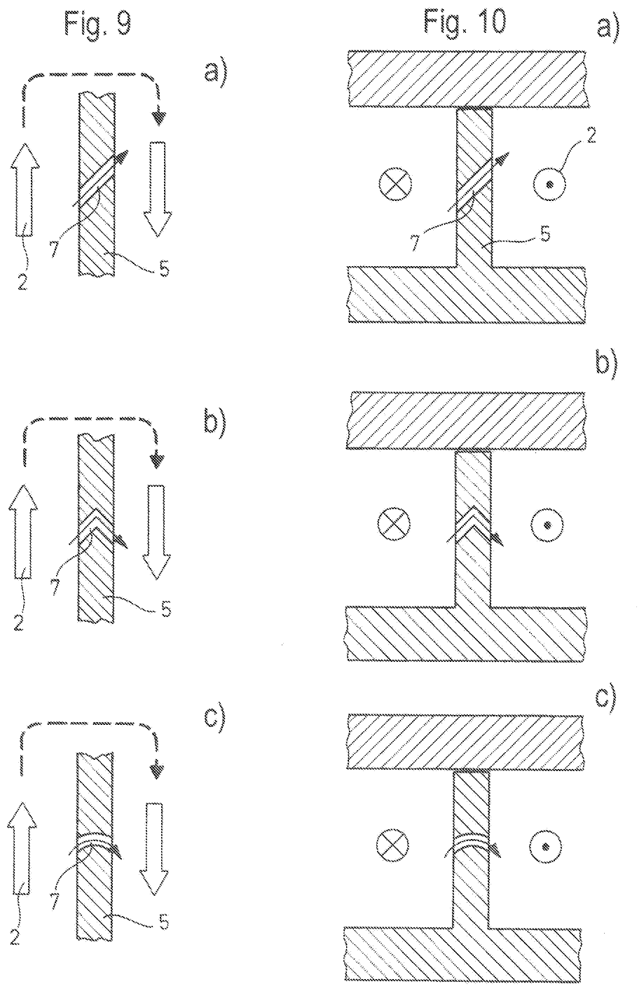

FIGS. 9a, b, c represent cross-sectional plan views of upstream meandering spaces with its respective neighboring meandering space. FIGS. 9a, b, c represent various shapes and orientations of bypass passages 7 within the guide wall sections 5. In FIG. 9a the bypass passage is, with regard to the longitudinal direction of the fluid flow 2, inclined by an angle α so as to be able to separate a portion of the fluid flow 2 through the bypass passage 7 from the meandering chamber to its neighboring meandering chamber.

On principle, the same is true for the embodiment according to FIG. 9b. It can be seen, that the bypass passage is arranged such that the bypass passage turns its direction approximately rectangularly from left down to in the middle up and from there, right down at the exit of the separated part of the fluid flow 2. Again the subsequent meandering space is connected from the prevailing meandering space because the guide wall sections are alternatingly arranged with bypass passages through which the portion of the fluid flow from the fluid flow 2 is directed first upwards and then downwards. The same principle applies to FIG. 9c except that the bypass passage does not have corner edges, rather, it is arranged as a rounded bypass passage.

At last, FIG. 10 shows a cross-sectional view of two neighboring meandering spaces wherein the fluid flow is flowing in one direction in the left chamber and in the opposite direction in the right chamber these two chambers being connected by a bypass passage which again has the shape and arrangement similar to what has been represented in FIGS. 9a, b and c. The representation in FIG. 10 represents the inclination of the bypass passage with regard to angle β.

While the present disclosure has been illustrated and described with respect to a particular embodiment thereof, it should be appreciated by those of ordinary skill in the art that various modifications to this disclosure may be made without departing from the spirit and scope of the present disclosure.

What is claimed is:

1. A flow distributor for distributing a heat transporting fluid flow of an electrical component across a surface to be cooled and/or heated by the fluid, the distributor comprising:
a) at least one flow channel configured to direct the fluid flow across the surface,
b) the flow channels being separated from each other and delimited on either side by walls so as to form a path for the fluid flow within the flow channels, and comprising wall sections extending into the at least one flow channel; and
c) at least one of the wall sections comprising at least one bypass passage to connect two adjacent spaces separated by the wall section, where the at least one bypass passage extends from one side of the wall section to the other with an inclined orientation so as to create a short circuit fluid flow for a part of the fluid flow.

2. The flow distributor according to claim 1 wherein the wall section comprises at least one bypass passage the inclined orientation of which having a first angle α with regard to the longitudinal direction of the walls, the first angle α of inclination facing towards the flow direction of the fluid flow so as to bypass a part of the fluid flow and to increase swirl of the heat transporting fluid flow within the flow channels.

3. The flow distributor according to claim 1, wherein the bypass passage comprises a second angle β of inclination with regard to a horizontal plane through wall sections extending perpendicularly to the horizontal plane.

4. The flow distributor according to claim 1, wherein those wall sections comprising at least one bypass passage each comprise a plurality of bypass passages, in particular the wall sections being perforated.

5. The flow distributor according to claim 1, wherein the dimensions of the bypass passages are such that up to 40%, in particular up to 30%, more particular up to 15 to 20%, and even more particular up to 10 to 15% of the fluid flow is conducted through the bypass passages to the respective space within the flow channel.

6. A flow distributor for distributing a heat transporting fluid flow of an electrical component across a surface to be cooled and/or heated by the fluid, the distributor comprising:
a) at least one flow channel configured to direct the fluid flow across the surface,
b) the flow channels being separated from each other and delimited on either side by baffle walls extending in longitudinal direction of the flow channels and comprising guide wall sections extending substantially perpendicular to the longitudinal direction of the flow channels so as to form a meandering path for the fluid flow within the flow channels; and
c) at least one of the guide wall sections comprising at least one bypass passage to connect two adjacent meandering spaces separated by the guide wall section, where the at least one bypass passage extends from one side of the guide wall section to the other with an inclined orientation so as to create a short circuit fluid flow for a part of the fluid flow.

7. The flow distributor according to claim 6, wherein the guide wall section comprises at least one bypass passage the inclined orientation of which having a first angle α with regard to the longitudinal direction of the baffle walls, the first angle α of inclination facing towards the flow direction of the fluid flow so as to bypass a part of the fluid flow and to increase swirl of the heat transporting fluid flow within the flow channels.

8. The flow distributor according to claim 6, wherein the bypass passage comprises a second angle β of inclination with regard to a horizontal plane through guide wall sections extending perpendicularly to the horizontal plane.

9. The flow distributor according to claim 6, wherein those guide wall sections comprising at least one bypass passage each comprise a plurality of bypass passages, in particular the guide wall sections being perforated.

10. The flow distributor according to claim 6, wherein the dimensions of the bypass passages are such that up to 40%, in particular up to 30%, more particular up to 15 to 20%, and even more particular up to 10 to 15% of the fluid flow is conducted through the bypass passages to the respective meandering space within the flow channel.

11. The flow distributor according to any onc of claims claim 1, comprising a housing having the inlet manifold and the outlet manifold for the fluid flow and comprising a bathtub for receiving an insert with the wall structure of the fluid distributor, the insert being covered by a closing plate to seal the bathtub towards outside.

12. The flow distributor according to claim 11, wherein the insert comprises a two-part design with a lower structure and an upper counter structure each having a wall structure to fit to each other when assembled and its closing plate being integrally formed with the upper counter structure.

13. A semiconductor module comprising the flow distributor according to claim 1.

14. An insert with a wall structure of a flow distributor according to claim 1, manufactured by 3D-printing or injection molding

15. Method A method of manufacturing a flow distributor wherein an insert with the wall structure of the flow distributor according to claim 1 is manufactured by injection molding.

16. The method of manufacturing a flow distributor wherein an insert with a wall structure of the flow distributor according to claim 1 is manufactured by 3D-printing, comprising the steps of:
a) providing a computer-readable medium having computer-executable instructions adapted to cause a 3D-printer to print the flow distributor; and
b) forming the flow distributor using a 3D-printing or additive manufacturing apparatus.

17. A computer-readable medium having computer-executable instructions adapted to cause a 3D-printer to print a flow distributor according to claim 1.

18. The flow distributor according to claim 2, wherein the bypass passage comprises a second angle β of inclination with regard to a horizontal plane through wall sections extending perpendicularly to the horizontal plane.

19. The flow distributor according to claim 2, wherein those wall sections comprising at least one bypass passage each comprise a plurality of bypass passages, in particular the wall sections being perforated.

20. The flow distributor according to claim 3, wherein those wall sections comprising at least one bypass passage each comprise a plurality of bypass passages, in particular the wall sections being perforated.
